(19) United States
(12) Patent Application Publication
(10) Pub. No.: US 2026/0369859 A1
(43) Pub. Date: Nov. 19, 2026

(54) POWER DIVIDER/COMBINER INCLUDING DIRECTIONAL COUPLER

(71) Applicant: SAMSUNG ELECTRONICS CO., LTD., Suwon-si (KR)

(72) Inventors: Jaeyeon JEONG, Suwon-si (KR); Geuntae Kim, Busan (KR); Ockgoo Lee, Busan (KR); Chanhong Park, Suwon-si (KR); Hyunchul Park, Suwon-si (KR)

(73) Assignees: SAMSUNG ELECTRONICS CO., LTD., Suwon-si (KR); PUSAN NATIONAL UNIVERSITY INDUSTRY-UNIVERSITY COOPERATION FOUNDATION, Busan (KR)

(21) Appl. No.: 19/465,548

(22) Filed: Jan. 30, 2026

(30) Foreign Application Priority Data
May 19, 2025 (KR) 10-2025-0064917

(51) Int. Cl. H01P 5/18; H03F 3/60

(52) U.S. Cl. CPC H01P 5/18; H03F 3/602; H03F 2200/451

(57) ABSTRACT

A power divider/combiner includes a first directional coupler connected between a first port and a second port, a capacitor connected in parallel to the first port, and a second directional coupler connected between the first port and a third port. A first input port of the first directional coupler is connected to the first port, a first output port of the first directional coupler is connected to the second port, a first coupling port of the first directional coupler is serially connected to a second coupling port of the second directional coupler through a resistor, and a first isolation port of the first directional coupler corresponds to a second isolation port of the second directional coupler. A second input port of the second directional coupler is connected to the first port, and a second output port of the second directional coupler is connected to the second port.

### CROSS-REFERENCE TO RELATED APPLICATION

This application is based on and claims priority under 35 U.S.C. § 119 to Korean Patent Application No. 10-2025-0064917, filed on May 19, 2025, in the Korean Intellectual Property Office, the disclosure of which is incorporated by reference herein in its entirety.

### BACKGROUND

The present disclosure relates to a power divider/combiner, and more particularly, to a power divider/combiner including a directional coupler.

Radio frequency (RF) power combiners/dividers are used in communication systems, radars, and various RF application fields. RF power combiners combine multiple signals and transmit the result of the combination to a single output, and RF power dividers divide a single signal into multiple outputs. In particular, RF power combiners and dividers are utilized to combine or split the power of RF transmitters to produce large power for wireless communication.

For example, power combiners/dividers are commonly used in power amplifiers of transmitting terminals that require large output power, and the powers obtained by power dividers are amplified through power amplifiers and then combined through a power combiner. Related art circuits for dividing/combining power include a Wilkinson divider/combiner and a directional divider/combiner. However, these circuits require λ/4 electrical lengths. Accordingly, there are limitations on the miniaturization and design freedom of electronic devices.

### SUMMARY

According to an aspect of the disclosure, a power divider/combiner includes: a first directional coupler connected between a first port and a second port; a capacitor connected in parallel to the first port; a resistor; and a second directional coupler connected between the first port and a third port, wherein the first directional coupler includes: a first input port connected to the first port; a first output port connected to the second port; a first coupling port and a first isolation port, wherein the second direction coupler includes: a second input port connected to the first port; a second output port connected to the third port; a second coupling port; and a second isolation port, wherein the first isolation port and the second isolation port correspond to a same node, and wherein the resistor is connected in series between the first coupling port and the second coupling port.

According to an aspect of the disclosure, an electronic device includes: a processor; a memory; and a communication circuit including a radio frequency (RF) amplification module, wherein the RF amplification module includes: a power divider configured to equally divide an input signal into a first signal and a second signal; a first power amplifier configured to amplify the first signal and output a third signal; a second power amplifier configured to amplify the second signal and outputs a fourth signal; and a power combiner configured to combine the third signal with the fourth signal to generate an output signal.

### BRIEF DESCRIPTION OF THE DRAWINGS

Embodiments will be more clearly understood from the following detailed description taken in conjunction with the accompanying drawings in which:

FIG. 1 is a block diagram of an electronic device according to an embodiment;

FIG. 2 is a diagram illustrating a structure of a communication circuit according to an embodiment;

FIG. 3 is a block diagram of a transmission path according to one or more embodiments;

FIG. 4 is a block diagram of a radio frequency (RF) amplification module according to one or more embodiments;

FIG. 5 is a diagram illustrating a power divider/combiner according to one or more embodiments;

FIG. 6 is a diagram illustrating an even mode of a power divider/combiner according to one or more embodiments;

FIG. 7 is a diagram illustrating an odd mode of a directional coupler according to one or more embodiments;

FIG. 8 is a diagram illustrating an RF amplification module according to one or more embodiments;

FIG. 9 is a graph showing a variation in an S-parameter according to an operating frequency, according to one or more embodiments; and

FIG. 10 is a block diagram of a wireless communication device according to an embodiment.

### DETAILED DESCRIPTION

The example embodiments described herein are provided so that this disclosure will be thorough and complete, and will fully convey the scope of the disclosure to one of ordinary skill in the art. As the disclosure allows for various changes and numerous embodiments, particular example embodiments will be illustrated in the drawings and described in detail in the written description. However, this is not intended to limit the disclosure to particular modes of practice, and it is to be appreciated that all changes, equivalents, and substitutes that do not depart from the spirit and technical scope of the disclosure are encompassed in the disclosure. In the drawings, like reference numerals denote like elements. In the attached drawings, the dimensions of the structures are shown enlarged or reduced from the actual dimensions to ensure clarity of the disclosure.

The terms used in the disclosure are merely used to describe particular embodiments, and are not intended to limit the disclosure. An expression used in the singular encompasses the expression of the plural, unless it has a clearly different meaning in the context. In the present specification, it is to be understood that the terms such as “including”, “having”, etc., are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

Unless defined differently, all terms used in the description including technical and scientific terms have the same meaning as generally understood by one of ordinary skill in the art to which the disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be described with reference to the accompanying drawings. In the drawings, like elements are denoted by like reference numerals, and a repeated explanation thereof will not be given.

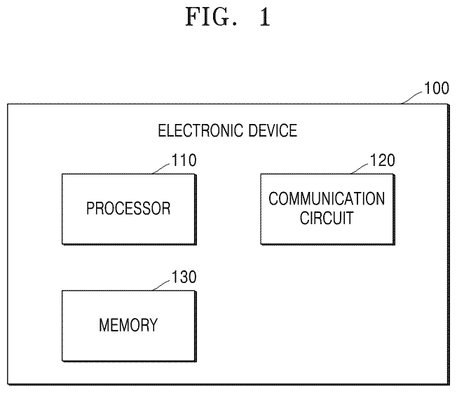

FIG. 1 is a block diagram of an electronic device 100 according to an embodiment.

Referring to FIG. 1, the electronic device 100 according to an embodiment may include a processor 110, a communication circuit 120, and a memory 130.

According to an embodiment, the processor 110 may control overall operations of the electronic device 100. For example, the processor 110 may transmit and receive a signal through the communication circuit 120. The processor 110 may write data to and read data from the memory 130. To this end, the processor 110 may include at least one processor or micro-processor or may be a portion of a processor. When the processor 110 is a portion of a processor, a portion of the communication circuit 120 and the processor 110 may be referred to as a communication processor.

According to an embodiment, the communication circuit 120 may perform functions for transmitting/receiving a signal through a wireless channel. For example, the communication circuit 120 may perform conversion between a baseband signal and a bitstream according to physical layer specifications of a system. For example, during data transmission, the communication circuit 120 may generate complex symbols by encoding and modulating a transmission bitstring, and, during data reception, the communication circuit 120 may restore a reception bitstring by demodulating and decoding a baseband signal. The communication circuit 120 may up-convert the baseband signal into a radio frequency (RF) band signal and then transmit the RF band signal through an antenna, or may down-convert the RF band signal received through the antenna into a baseband signal. For example, the communication circuit 120 may include a transmitting filter, a receiving filter, an amplifier, a mixer, an oscillator, a digital-to-analog converter (DAC), an analog-to-digital converter (ADC), etc. The communication circuit 120 may perform beamforming. The communication circuit 120 may apply a beamforming weight to a signal desired to be transmitted/received, in order to assign directivity to the signal.

According to an embodiment, the communication circuit 120 may transmit/receive a signal. The communication circuit 120 may receive a downlink signal. The downlink signal may include a synchronization signal (SS), a reference signal (RS), system information, a configuration message, control information, and/or downlink data. The communication circuit 120 may transmit an uplink signal. The uplink signal may include a random access related signal, a reference signal (e.g., a sounding reference signal (SRS) or a demodulation reference signal (DM-RS)), and/or uplink data.

The memory 130 may store data such as a basic program, an application program, and configuration data for an operation of the electronic device 100. The memory 130 may be implemented as a volatile memory, a non-volatile memory, or a combination of a volatile memory and a non-volatile memory. The memory 130 may provide stored data, according to a request of the processor 110.

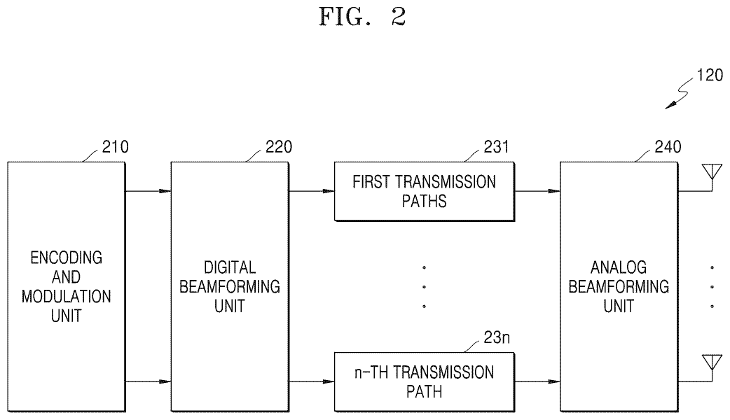

FIG. 2 is a diagram illustrating a structure of a communication circuit according to an embodiment.

Referring to FIG. 2, a communication circuit 120 (e.g., the communication circuit 120 of FIG. 1) includes an encoding and modulation unit 210, a digital beamforming unit 220, a plurality of transmission paths including first through n-th transmission paths 231 through 23n, and an analog beamforming unit 240.

According to an embodiment, the encoding and modulation unit 210 may perform channel encoding. For channel encoding, a low density parity check (LDPC) code, a convolution code, and/or a polar code may be used. The encoding and modulation unit 210 may generate modulation symbols by performing constellation mapping.

According to an embodiment, the digital beamforming unit 220 may perform beamforming on a digital signal (e.g., modulation symbols). To this end, the digital beamforming unit 220 may multiply the modulation symbols by beamforming weights. The beamforming weights may be used to change the magnitude and phase of a signal, and may be referred to as a ‘precoding matrix’, a ‘precoder’, or the like. The digital beamforming unit 220 may output digitally-beamformed modulation symbols to the first through n-th transmission paths 231-i through 231-n. At this time, according to a multiple input multiple output (MIMO) transmission technique, the modulation symbols may be multiplexed, or same modulation symbols may be provided to the first through n-th transmission paths 231-1 through 231-n.

According to an embodiment, the first through n-th transmission paths 231-1 through 231-n may convert digitally-beamformed digital signals into an analog signals. To this end, each of the first through n-th transmission paths 231-1 through 231-n may include an Inverse Fast Fourier Transform (IFFT) operation unit, a cyclic prefix (CP) insertion unit, a DAC, and an up-conversion unit. The CP insertion unit is for an orthogonal frequency division multiplexing (OFDM) method, and may be excluded when another physical layer method (e.g., a filter bank multi-carrier (FBMC)) is applied. That is, the first through n-th transmission paths 231-1 through 231-nn may provide independent signal processing processes for a plurality of streams generated through digital beamforming. According to implementation methods, some of the components of the first through n-th transmission paths 231-1 through 231-n may be used in common.

According to an embodiment, the analog beamforming unit 240 may perform beamforming on an analog signal. To this end, the analog beamforming unit 240 may multiply the analog signals by beamforming weights that may be used to change the magnitude and phase of a signal.

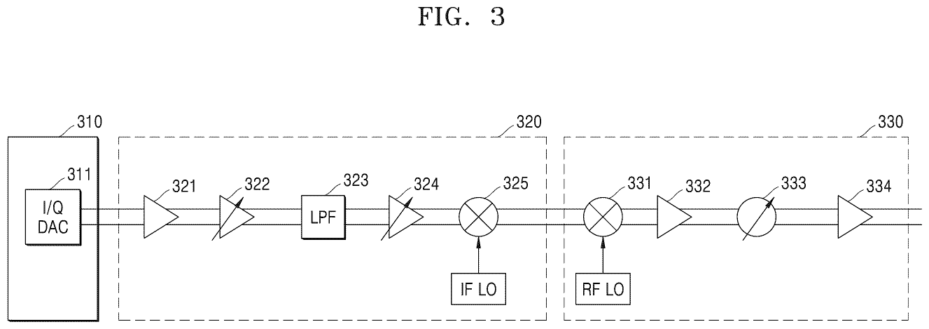

FIG. 3 is a block diagram of a transmission path according to one or more embodiments.

Referring to FIG. 3, the transmission path may correspond to any one of the first through n-th transmission paths 231-1 through 231-n of FIG. 2. The transmission path may include a transmission RF chain 330, a transmission intermediate frequency (IF) chain 320, and a communication processor 310. According to various embodiments, one or more components may be added to or may be omitted from the communication system.

According to an embodiment, the communication processor 310 may include a transmission in phase (I)/quadrature phase (Q) DAC 311. The transmission I/Q DAC 311 may convert a digital signal modulated by a modem into a balanced I signal and a balanced Q signal and may transmit the balanced I signal and the balanced Q signal to the IF chain 320. According to various embodiments, the communication processor 310 may be implemented using a special chip, or may be integrated with another component into a single chip.

According to an embodiment, the transmission IF chain 320 may include a transmission IF buffer 321, a first transmission variable gain amplifier (VGA) 322, a low pass filter (LPF) 323, a second transmission VGA 324, and a transmission IF mixer 325.

According to an embodiment, when the transmission IF buffer 321 receives the balanced I signal and the balanced Q signal from the communication processor 310, the transmission IF buffer 321 may perform a buffering role, and thus the transmission IF chain 320 may stably process the balanced I signal and the balanced Q signal. The LPF 323 may filter a signal by using the bandwidth of the baseband signal as a cutoff frequency. The cutoff frequency may be variable. The first transmission VGA 322 and the second transmission VGA 324 may receive a control signal from the communication processor 310 and perform transmission auto gain control (AGC) on the received signal. For example, the first transmission VGA 322 may perform the AGC on the balanced I signal and the balanced Q signal from the transmission IF buffer 321. The second transmission VGA 324 may perform the AGC on filtered signal from the LPF 323. In the above-described embodiment, the number of VGAs is illustrated as two. However, embodiments are not limited thereto. The transmission IF mixer 325 may receive a frequency signal corresponding to an IF signal band from a local oscillator (LO), and may convert a balanced I signal and a balanced Q signal corresponding to a baseband into an IF signal, based on the frequency signal.

According to an embodiment, the transmission RF chain 330 may include a transmission RF mixer 331, a transmission driving amplifier (DA) 332, a phase shifter 333, a transmission power amplifier (PA) 334.

According to an embodiment, the transmission RF mixer 331 may receive the IF signal from the transmission IF chain 320, and may up-convert the IF signal into an RF signal, based on the frequency signal received from the LO. The transmission DA 332 may amplify the RF signal obtained by the transmission RF mixer 331 through the up-conversion. The phase shifter 333 may change the phase of the RF signal according to a beamforming angle, based on the control signal received from the communication processor 310. The transmission PA 334 may amplify power when the RF signal is transmitted. The transmission PA 334 may be outside or embedded inside the transmission RF chain 330. The transmission RF mixer 331 may be connected to the transmission DA 332 through one or more filters.

In the above-described embodiment, a transmission path including a transmission IF chain and a transmission path including a transmission RF chain are illustrated. However, embodiments are not limited thereto.

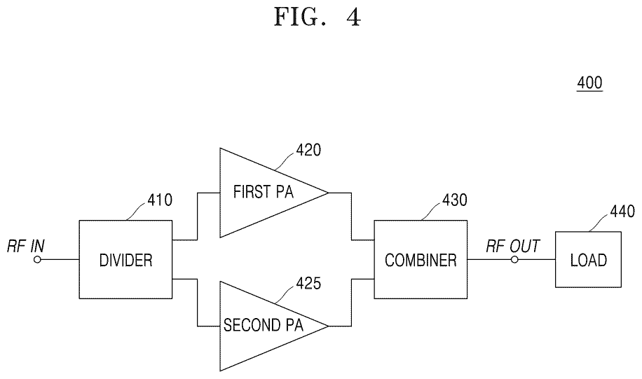

FIG. 4 is a block diagram of an RF amplification module 400 according to an embodiment.

Referring to FIG. 4, the RF amplification module 400 may include a divider 410, a first PA 420, a second PA 425, a combiner 430, and a load 440. According to various embodiments, the RF amplification module 400 may correspond to the amplifiers of FIG. 3 (e.g., the DA 332 or the PA 334 of FIG. 3). For example, the amplifiers of FIG. 3 may be implemented using the RF amplification module 400 of FIG. 4 due to non-linearity that occurs as an operating frequency increases (e.g., FR2).

According to an embodiment, the divider 410 may divide a signal into a plurality of signals. For example, the divider 410 may receive an input signal RF IN and divide the received input signal RF IN into two signals. Among the two signals, a first signal may be transmitted to the first PA 420, and a second signal may be transmitted to the second PA 425.

According to an embodiment, the first PA 420 and the second PA 425 may amplify and output signals. For example, the first PA 420 may receive the first signal from the divider 410, amplify the first signal, and output the amplified first signal to the combiner 430. The second PA 425 may receive the second signal from the divider 410, amplify the second signal, and output the amplified second signal to the combiner 430.

According to an embodiment, the combiner 430 may combine the plurality of signals. For example, the combiner 430 may receive the amplified first signal from the first PA 420 and receive the amplified second signal from the second PA 425. The combiner 430 may combine the amplified first signal with the amplified second signal and output an output signal RF OUT to the load 440.

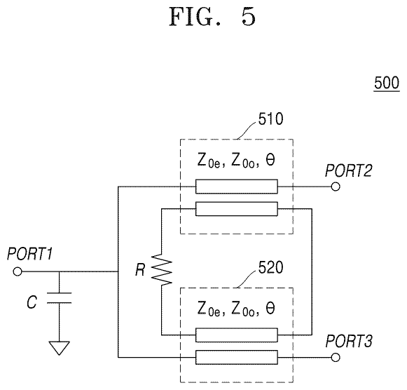

According to an embodiment, the divider 410 and the combiner 430 may include four-port directional couplers. That is, the divider 410 and the combiner 430 may have the same configuration as a power divider/combiner including directional couplers. For example, when the power divider/combiner receives one signal and splits the one signal into a plurality of signals, the power divider/combiner may operate as the divider 410. When the power divider/combiner receives a plurality of signals and combines the plurality of signals into one signal, the power divider/combiner may operate as the combiner 430. The power divider/combiner including directional couplers will be described later in detail with reference to FIG. 5.

According to an embodiment, the load 440 may receive the output signal RF OUT from the combiner 430. The load 440 may be referred to as a component connected to the next stage of the RF amplification module 400. For example, the load 440 may be an antenna connected to the last stage of the transmission RF chain 330 of FIG. 3.

FIG. 5 is a diagram illustrating a power divider/combiner 500 according to one or more embodiments.

Referring to FIG. 5, the power divider/combiner 500 may include a first directional coupler 510 and a second directional coupler 520. According to various embodiments, the power divider/combiner 500 may operate as a divider or may operate as a combiner. For example, referring to FIG. 2 together, the power divider/combiner 500 may operate as a divider when the analog beamforming unit 240 transmits transmission signals to a plurality of antennas, and may operate as a combiner when the analog beamforming unit 240 receives reception signals through the plurality of antennas.

According to an embodiment, when operating as a divider, the power divider/combiner 500 may receive one input signal and divide the received input signal into a plurality of output signals. For example, the power divider/combiner 500 may receive the input signal (e.g., the input signal RF IN of FIG. 4) through a first port PORT1. A capacitor C may be connected in parallel to a node that is the same as the first port PORT1. The first port PORT1 may be connected to the first directional coupler 510 and the second directional coupler 520. Referring to FIG. 4 together, when the power divider/combiner 500 receives the input signal RF IN through the first port PORT1, the power divider/combiner 500 may correspond to the divider 410 of FIG. 4.

According to an embodiment, the first directional coupler 510 may include four ports. The four ports may include an input port, an output port, a coupling port, and an isolation port. The input port of the first directional coupler 510 may be connected to the first port PORT1 of the divider 410. That is, a first signal divided by the first port PORT1 may be transmitted to the input port of the first directional coupler 510. The first directional coupler 510 may generate a first output signal based on the first signal, and the first output signal may be output through the output port of the first directional coupler 510. The output port of the first directional coupler 510 may correspond to a second port PORT2 of the divider 410. The coupling port of the first directional coupler 510 may be connected to the coupling port of the second directional coupler 520 through a resistor R. The isolation port of the first directional coupler 510 may correspond to a node that is the same as the isolation port of the second directional coupler 520.

According to an embodiment, the second directional coupler 520 may include four ports. The four ports may include an input port, an output port, a coupling port, and an isolation port. The input port of the second directional coupler 520 may be connected to the first port PORT1 of the divider 410. That is, a second signal divided by the first port PORT1 may be transmitted to the input port of the second directional coupler 520. The second directional coupler 520 may generate a second output signal based on the second signal, and the second output signal may be output through the output port of the second directional coupler 520. The output port of the second directional coupler 520 may correspond to a third port PORT3 of the divider 410. The coupling port of the second directional coupler 520 may be connected to the coupling port of the first directional coupler 510 through the resistor R. The isolation port of the second directional coupler 520 may correspond to a node that is the same as the isolation port of the first directional coupler 510.

According to an embodiment, when operating as a divider, the power divider/combiner 500 may receive a plurality of input signals and combine the plurality input signals into one output signal. For example, the power divider/combiner 500 may receive a first input signal through the second port PORT2 and a second input signal through the third port PORT3. The output port of the first directional coupler 510 and the output port of the second directional coupler 520 may be connected to the first port PORT1. Referring to FIG. 4 together, when the power divider/combiner 500 receives the first and second input signals through the second port PORT2 and the third port PORT3, the power divider/combiner 500 may correspond to the combiner 430 of FIG. 4.

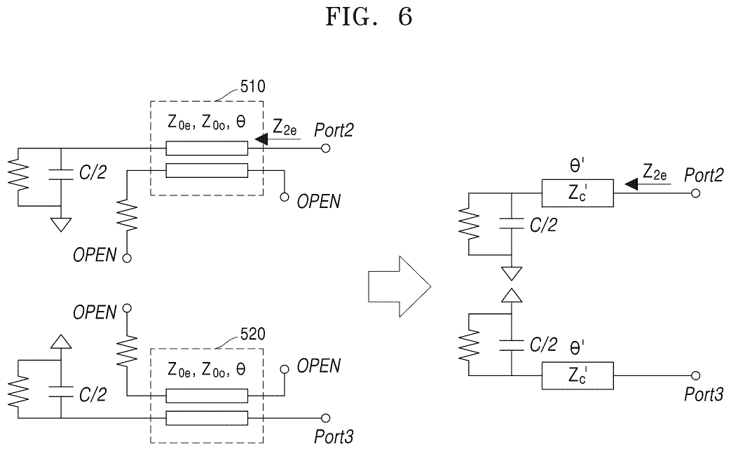

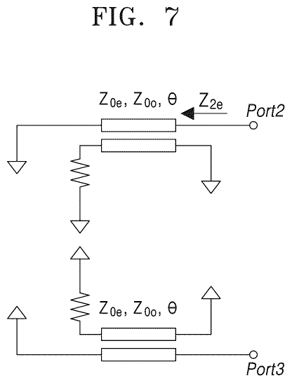

According to an embodiment, the first directional coupler 510 or the second directional coupler 520 may operate in an even mode or an odd mode. The even mode may correspond to a case where current directions of the first signal and the second signal are the same as each other, and the odd mode may correspond to a case where the current directions of the first signal and the second signal are opposite to each other. The even mode and the above odd mode will now be described with reference to FIGS. 6 and 7, respectively.

FIG. 6 is a diagram illustrating an even mode of a power divider/combiner according to one or more embodiments.

Referring to FIG. 6, when the power divider/combiner operates as a combiner (e.g., the combiner 430 of FIG. 4) and traveling directions of the first input signal and the second input signal are the same as each other, the combiner of FIG. 5 (e.g., the combiner 430 of FIG. 4) may be interpreted as being the same as a virtual open because the top and bottom are symmetrical to each other with respect to an X-axis. Therefore, a coupling port and an isolation port of a directional coupler in the even mode may be opened. For example, it may be interpreted that the isolation port of the first directional coupler 510 is disconnected from the isolation port of the second directional coupler 520 and the coupling port of the first directional coupler 510 is disconnected from the coupling port of the second directional coupler 520. When the coupling port and the isolation port are interpreted as a single line, the first directional coupler 510 and the second directional coupler 520 may be equivalent to a transmission line having characteristic impedance of Zc′.

According to an embodiment, the characteristic impedance Zc′ may be calculated by overlapping characteristic impedance Zoe of the even mode and characteristic impedance Zoo of the odd mode.

$${Zc}^{′} = \frac{{Z}_{0 e} + {Z}_{0 o}}{2} \qquad [ Equation 1 ]$$

When characteristic impedance based on an equivalent circuit of FIG. 6 is calculated based on impedance matching of 50 ohms (Ω), the characteristic impedance is calculated using the equations below.

$$50 \frac{( {Z}_{0 e} + {Z}_{0 o} )}{2} + \frac{5000 wC}{1 + {( 50 * w * C )}^{2}} tan θ = 2 \frac{( {Z}_{0 e} + {Z}_{0 o} )}{2} \frac{100}{1 + {( 50 * w * C )}^{2}} \qquad [ Equation 2 ]$$

$$\frac{100}{1 + {( 50 * w * C )}^{2}} tan θ = \frac{5000 wC}{1 + {( 50 * w * C )}^{2}} \frac{( {Z}_{0 e} + {Z}_{0 o} )}{2} + \frac{( {Z}_{0 e} + {Z}_{0 o} )}{2} tan θ \qquad [ Equation 3 ]$$

where w is an angular velocity, ⊖ is an electrical length, and C is a capacitance value of the capacitor C. By combining Equations 2 and 3 obtained according to a transmission line equation with respect to an arbitrary electrical length (θ) and an angular velocity w, values of parallels

$$\frac{C}{2} and \frac{{Z}_{0 e} + {Z}_{0 o}}{2}$$

having a value of 50Ω matched with a Z_{IN}(⊖)=Z₂ₑ port may be obtained.

FIG. 7 is a diagram illustrating an odd mode of a directional coupler according to one or more embodiments.

Referring to FIG. 7, when the traveling directions of the first signal and the second signal are opposite to each other, the first directional coupler 510 and the second directional coupler 520 may be interpreted as an equivalent circuit in which an input port and an isolation port are virtually grounded. When the input port and the isolation port are grounded, the directional coupler can be interpreted as a bandpass filter. In this case, Z₂ₒ may be the same as Equation 4 below.

$${Z}_{2 o} = \frac{2 {Z}_{0 e} {Z}_{0 o} sin θ}{\sqrt{{( {Z}_{0 e} - {Z}_{0 o} )}^{2} - {( {Z}_{0 e} + {Z}_{0 o} )}^{2} {cos}^{2} θ}} = 50 \qquad [ Equation 4 ]$$

Accordingly, a value of

$$\frac{{Z}_{0 e} - {Z}_{0 o}}{2}$$

may be calculated, and values of Z₀ₑ, Z₀ₒ, and C may be calculated via an arithmetic operation with the

$$\frac{{Z}_{0 e} - {Z}_{0 o}}{2}$$

value calculated using Equations 2 and 3. For example, an example of calculating the values Z₀ₑ, Z₀ₒ, and C satisfying the arbitrary electrical length (θ) is shown in Table 1 below. That is, referring to Table 1, even when the length of a transmission line is not limited to λ/4 as in the conventional art and various arbitrary lengths are determined, impedance matching may be obtained by calculating the values of Z₀ₑ, Z₀ₒ, and C satisfying Equation 1, Equation 2, and Equation 3 above.

TABLE 1

| Electrical length(°) | Z₀ₑ | Z₀ₒ | C(fF) |
|---|---|---|---|
| 25 | 247.186 | 10.1228 | 132.9 |
| 30 | 212.135 | 11.77 | 123.42 |
| 35 | 187.054 | 13.363 | 112.47 |
| 40 | 170.553 | 14.747 | 102.38 |
| 45 | 156.78 | 15.93 | 91.06 |
| 50 | 147.05 | 16.867 | 80.8 |

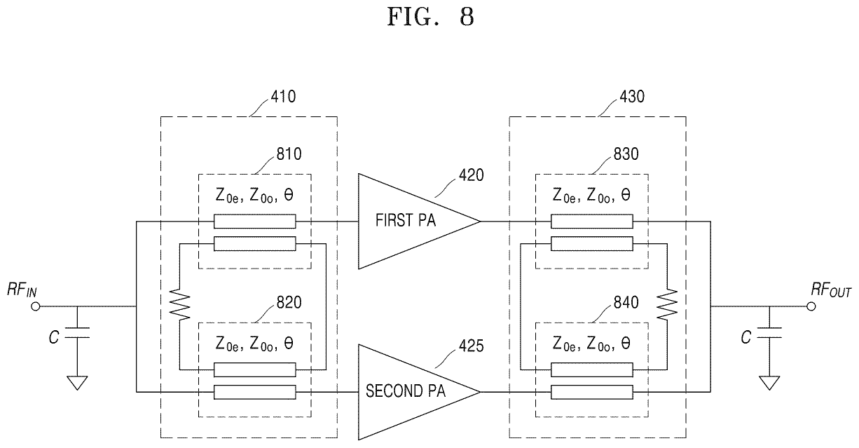

FIG. 8 is a diagram illustrating an RF amplification module according to one or more embodiments.

Referring to FIG. 8, the input signal RF IN may be transmitted to the divider 410. The divider 410 may include a first directional coupler 810 and a second directional coupler 820. The input signal RF IN may be divided into the first directional coupler 810 and the second directional coupler 820. Impedance matching may be achieved by calculating Z₀ₑ, Z₀ₒ, and C for a target electrical length θ and a target operating frequency

$$f = \frac{w}{2 π}$$

of the divider 410. Accordingly, the input signal RF IN may be distributed with equal power to the first PA 420 and the second PA 425, respectively. The first PA 420 may receive half of the input signal RF IN, amplify the half, and transmit the amplified half to the combiner 430. The second PA 425 may receive the other half of the input signal RF IN, amplify the other half, and transmit the amplified half to the combiner 430. The combiner 430 may include a third directional coupler 830 and a fourth directional coupler 840. Impedance matching may be achieved by calculating Z₀ₑ, Z₀ₒ, and C for the target electrical length θ and the target operating frequency f of the divider 430. According to an embodiment, the combiner 430 may combine the signals received by the first PA 420 and the second PA 425.

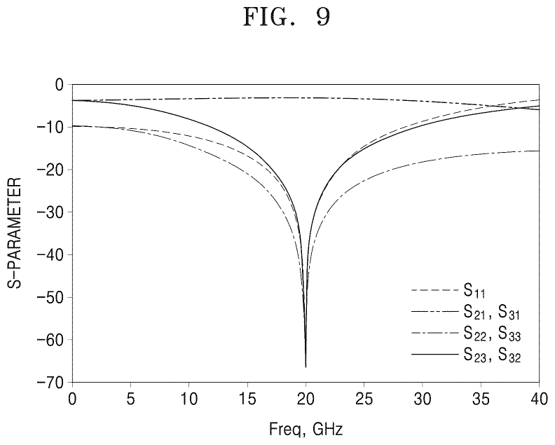

FIG. 9 is a graph showing a variation in an S-parameter according to an operating frequency, according to one or more embodiments.

Referring to FIG. 9, the X axis may have the X-axis corresponding to the operating frequency and the Y-axis may correspond to each S-parameter. The S-parameter may represent the ratio of an output signal to an input signal between ports of a power divider/combiner. For example, referring to FIG. 5 together, S21 represents a percentage of the signal transmitted to the second port PORT2 in the input signal of the first port PORT1, and S31 represents a percentage of the signal transmitted to the third port PORT3 in the input signals of the first port PORT1. S23 represents a percentage of the signal transmitted to the second port PORT2 in the input signal of the third port PORT3, and S32 represents a percentage of the signal transmitted to the third port PORT3 in the input signal of the second port PORT2. S12 represents a percentage of the signal transmitted to the first port PORT1 in the input signal of the second port PORT2, and S13 represents a percentage of the signal transmitted to the first port PORT1 in the input signal of the third port PORT3. S11, S22, and S33 may represent ratios between input signals and reflected output signals in the first port PORT1, the second port PORT2, and the third port PORT3, respectively. For example, when there is no reflected signal due to achievement of impedance matching, S11, S22, and S33 may be 0.

Referring to the graph, S-parameters are shown when an electrical length is λ/12) (30°) and a center frequency is 20 [GHz]. At the center frequency of 20 [GHz], S21 and S31 are −3 dB. That is, a signal input to the first port PORT1 may be output as half the power to each of the second port PORT2 and the third port PORT3. Based on the impedance matching, it may be confirmed that the values of the remaining S-parameters S11, S22, S33, S23, and S32 are close to 0.

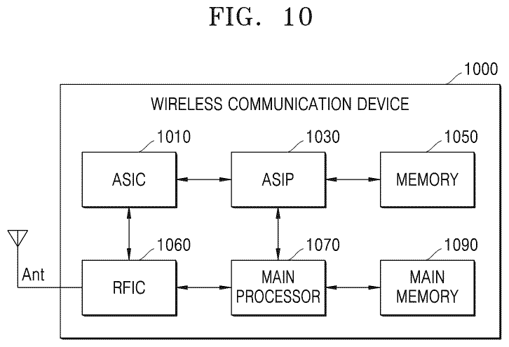

FIG. 10 is a block diagram of a wireless communication device according to an embodiment.

Referring to FIG. 10, a wireless communication device 1000 may include a modem (not shown) and a radio frequency integrated circuit (RFIC) 1060, and the modem may include an Application Specific Integrated Circuit (ASIC) 1010, an Application Specific Instruction set Processor (ASIP) 1030, a memory 1050, a main processor 1070, and a main memory 1090. The wireless communication device 1000 of FIG. 10 may be the electronic device 100 according to an embodiment.

The RFIC 1060 may be connected to an antenna Ant and may receive a signal from the outside or transmit a signal to the outside by using a wireless communication network. The ASIP 1030 may be an integrated circuit customized for a use purpose. The ASIP 1030 may support an instruction set only for a certain application and may execute instructions included in the instruction set. The memory 1050 may communicate with the ASIP 1030 and may store, as a non-transitory storage, the instructions executed by the ASIP 1030. For example, as a non-limiting example, the memory 1050 may include an arbitrary type of memory accessed by the ASIP 1030, for example, Random Access Memory (RAM), Read Only Memory (ROM), a tape, a magnetic disk, an optical disk, a volatile memory, a non-volatile memory, and a combination thereof.

The main processor 1070 may execute the instructions and thus may control the wireless communication device 1000. For example, the main processor 1070 may control the ASIC 1010 and the ASIP 1030 and may process data received via a wireless communication network or a user input to the wireless communication device 1000.

The main memory 1090 may communicate with the main processor 1070 and may store, as a non-transitory storage, the instructions executed by the main processor 1070. For example, as a non-limiting example, the main memory 1090 may include an arbitrary type of memory accessed by the main processor 1070, for example, RAM, ROM, a tape, a magnetic disk, an optical disk, a volatile memory, a non-volatile memory, and a combination thereof.

Each component of a device or a method according to the disclosure may be implemented as hardware or software, or as a combination of hardware and software. In addition, the function of each component may be implemented as software, and a microprocessor may be implemented to execute the function of the software corresponding to each component.

Various implementations of systems and techniques described herein may be realized in digital electronic circuits, integrated circuits, field programmable gate arrays (FPGAs), ASICs, computer hardware, firmware, software, and/or combinations thereof. These various implementations may include implementations as one or more computer programs executable on a programmable system. The programmable system includes at least one programmable processor (which may be a special purpose processor or a general purpose processor) coupled to receive data and commands from and transmit data and commands to a storage system, at least one input device, and at least one output device. Computer programs (also known as programs, software, software applications or code) include instructions for a programmable processor and are stored on a “computer-readable recording medium”.

The computer-readable recording medium is any type of recording device that stores data which can thereafter be read by a computer system. Such computer-readable recording medium may be a non-volatile or non-transitory medium such as ROM, a CD-ROM, a magnetic tape, a floppy disk, a memory card, a hard disk, a magneto-optical disk, or storage device, and may further include a transitory medium such as a data transmission medium. The computer-readable recording medium may also be distributed over network-coupled computer systems so that the computer readable code is stored and executed in a distributive manner.

Although the flowchart/timing diagram in this specification describes processes as being executed sequentially, this is merely an example to explain the technical idea of embodiments. In other words, because a person having ordinary skill in the art to which embodiments pertain may variously modify and apply the flowchart/timing diagram by changing the order described in the flowchart/timing diagram and executing processes or executing one or more of the processes in parallel, without departing from the essential characteristics of embodiments, the flowchart/timing diagram is not limited to a chronological order.

While example embodiments have been particularly shown and described, it will be understood by those of ordinary skill in the art that various changes in form and details may be made therein without departing from the spirit and scope as defined by the following claims. Therefore, the example embodiments should be considered in descriptive sense only and not for purposes of limitation. The scope of the present disclosure is defined not by the detailed description of the present disclosure but by the appended claims, and all technical spirits within the scope will be construed as being included in the present disclosure.

What is claimed is:

1. A power divider/combiner comprising:
a first directional coupler connected between a first port and a second port;
a capacitor connected in parallel to the first port;
a resistor; and
a second directional coupler connected between the first port and a third port,
wherein the first directional coupler comprises:
a first input port connected to the first port;
a first output port connected to the second port;
a first coupling port and
a first isolation port,
wherein the second direction coupler comprises:
a second input port connected to the first port;
a second output port connected to the third port;
a second coupling port; and
a second isolation port,
wherein the first isolation port and the second isolation port correspond to a same node, and
wherein the resistor is connected in series between the first coupling port and the second coupling port.

2. The power divider/combiner of claim 1, wherein a characteristic impedance of the first directional coupler and the second directional coupler corresponds to an average a first impedance of an even mode of the power divider/combiner and a second impedance of an odd mode of the power divider/combiner.

3. The power divider/combiner of claim 2, wherein impedance matching of the power divider/combiner corresponds to 50 ohms.

4. The power divider/combiner of claim 3, wherein the even mode corresponds to a state in which input signals of the first directional coupler and the second directional coupler are in phase, and
wherein the odd mode corresponds to a state in which the input signals of the first directional coupler and the second directional coupler are in anti-phase.

5. The power divider/combiner of claim 4, wherein, in the even mode, based on a target electrical length and a target operating frequency of the first directional coupler and the second directional coupler, the characteristic impedance corresponds to a combination of the following equations:
$$\frac{100}{1 + {( 50 * w * C )}^{2}} tan θ = \frac{5000 wC}{1 + {( 50 * w * C )}^{2}} \frac{( {Z}_{0 e} + {Z}_{0 o} )}{2} + \frac{( {Z}_{0 e} + {Z}_{0 o} )}{2} tan θ , and$$
$$50 \frac{( {Z}_{0 e} + {Z}_{0 o} )}{2} + \frac{5000 wC}{1 + {( 50 * w * C )}^{2}} tan θ = 2 \frac{( {Z}_{0 e} + {Z}_{0 o} )}{2} \frac{100}{1 + {( 50 * w * C )}^{2}} ,$$
wherein θ is the target electrical length, w is a target angular velocity, Z₀ₑ is the first impedance, Z₀ₒ is the second impedance, and C is a capacitance value of the capacitor.

6. The power divider/combiner of claim 5, wherein, in the odd mode, based on the target electrical length and the target operating frequency of the first directional coupler and the second directional coupler, a difference between the first impedance and the second impedance is obtained by the following equation
$$50 = \frac{2 {Z}_{0 e} {Z}_{0 o} sin θ}{\sqrt{{( {Z}_{0 e} - {Z}_{0 o} )}^{2} - {( {Z}_{0 e} + {Z}_{0 o} )}^{2} {cos}^{2} θ}} .$$

7. The power divider/combiner of claim 6, wherein each of the first impedance and the second impedance is based on the difference between the first impedance and the second impedance and the characteristic impedance.

8. An electronic device comprising:
a processor;
a memory; and
a communication circuit comprising a radio frequency (RF) amplification module,
wherein the RF amplification module comprises:
a power divider configured to equally divide an input signal into a first signal and a second signal;
a first power amplifier configured to amplify the first signal and output a third signal;
a second power amplifier configured to amplify the second signal and outputs a fourth signal; and
a power combiner configured to combine the third signal with the fourth signal to generate an output signal.

9. The electronic device of claim 8, wherein the power divider comprises:
a first directional coupler connected between a first port and a second port;
a first capacitor connected in parallel to the first port
a first resistor; and
a second directional coupler connected between the first port and a third port,
wherein the first direction coupler comprises:
a first input port connected to the first port;
a first output port connected to the second port;
a first coupling port; and
a first isolation port,
wherein the second direction coupler comprises:
a second input port connected to the first port;
a second output port connected to the third port;
a second coupling port; and
a second isolation port,
wherein the first isolation port and the second isolation port correspond to a same node, and
wherein the first resistor is connected in series between the first coupling port and the second coupling port.

10. The electronic device of claim 9, wherein a characteristic impedance of the first directional coupler and the second directional coupler corresponds to an average of a first impedance of an even mode of the power divider and a second impedance of an odd mode of the power divider.

11. The electronic device of claim 10, wherein impedance matching of the power divider corresponds to 50 ohms.

12. The electronic device of claim 11, wherein, in the even mode, based on a target electrical length and a target operating frequency of the first directional coupler and the second directional coupler, the characteristic impedance corresponds to a combination of the following equations:
$$\frac{100}{1 + {( 50 * w * C )}^{2}} tan θ = \frac{5000 wC}{1 + {( 50 * w * C )}^{2}} \frac{( {Z}_{0 e} + {Z}_{0 o} )}{2} + \frac{( {Z}_{0 e} + {Z}_{0 o} )}{2} tan θ , and$$
$$50 \frac{( {Z}_{0 e} + {Z}_{0 o} )}{2} + \frac{5000 wC}{1 + {( 50 * w * C )}^{2}} tan θ = 2 \frac{( {Z}_{0 e} + {Z}_{0 o} )}{2} \frac{100}{1 + {( 50 * w * C )}^{2}}$$
wherein θ is the target electrical length, w is a target angular velocity, Z₀ₑ is the first impedance, Z₀ₒ is the second impedance, and C is a capacitance value of the capacitor.

13. The electronic device of claim 12, wherein, in the odd mode, based on the target electrical length and the target operating frequency of the first directional coupler and the second directional coupler, a difference between the first impedance and the second impedance is obtained by the following equation:
$$50 = \frac{2 {Z}_{0 e} {Z}_{0 o} sin θ}{\sqrt{{( {Z}_{0 e} - {Z}_{0 o} )}^{2} - {( {Z}_{0 e} + {Z}_{0 o} )}^{2} {cos}^{2} θ}} .$$

14. The electronic device of claim 8, wherein the power combiner comprises:
a third directional coupler connected between a fourth port and a sixth port;
a second capacitor connected in parallel to the sixth port;
a second resistor; and
a fourth directional coupler connected between a fifth port and the sixth port,
wherein the third directional coupler comprises:
a third input port connected to the fourth port;
a third output port connected to the sixth port;
a third coupling port; and
a third isolation port, and
wherein the fourth directional coupler comprises:
a fourth input port connected to the fifth port;
a fourth output port connected to the sixth port;
a fourth coupling port; and
a fourth isolation port,
wherein the third isolation port and the fourth isolation port correspond to a same node, and
wherein the second resistor is connected in series between the third coupling port and the fourth coupling port.

15. The electronic device of claim 14, wherein a characteristic impedance of the third directional coupler and the fourth directional coupler corresponds to an average of a third impedance of an even mode of the power combiner and a fourth impedance of an odd mode of the power combiner.

16. The electronic device of claim 15, wherein impedance matching of the power combiner corresponds to 50 ohms.

17. The electronic device of claim 16, wherein in the even mode, based on a target electrical length and a target operating frequency of the third directional coupler and the fourth directional coupler, the characteristic impedance corresponds to a combination of the following equations:
$$\frac{100}{1 + {( 50 * w * C )}^{2}} tan θ = \frac{5000 wC}{1 + {( 50 * w * C )}^{2}} \frac{( {Z}_{0 e} + {Z}_{0 o} )}{2} + \frac{( {Z}_{0 e} + {Z}_{0 o} )}{2} tan θ , and$$
$$50 \frac{( {Z}_{0 e} + {Z}_{0 o} )}{2} + \frac{5000 wC}{1 + {( 50 * w * C )}^{2}} tan θ = 2 \frac{( {Z}_{0 e} + {Z}_{0 o} )}{2} \frac{100}{1 + {( 50 * w * C )}^{2}} ,$$
wherein θ is the target electrical length, w is a target angular velocity, Z₀ₑ is the first impedance, Z₀ₒ is the second impedance, and C is a capacitance value of the second capacitor.

18. The electronic device of claim 17, wherein, in the odd mode, based on a target electrical length and a target operating frequency of the third directional coupler and the fourth directional coupler, a difference between the first impedance and the second impedance is obtained by the following equation:
$$50 = \frac{2 {Z}_{0 e} {Z}_{0 o} sin θ}{\sqrt{{( {Z}_{0 e} - {Z}_{0 o} )}^{2} - {( {Z}_{0 e} + {Z}_{0 o} )}^{2} {cos}^{2} θ}} .$$

19. The electronic device of claim 18, wherein each of the third impedance and the fourth impedance is based on a difference between the third impedance and the fourth impedance and the characteristic impedance.

20. The electronic device of claim 18, wherein an output terminal of the RF amplification module is connected to an antenna.
